(19) United States
(12) Patent Application Publication
(10) Pub. No.: US 2024/0420932 A1
(43) Pub. Date: Dec. 19, 2024

(54) SUBSTRATE SUPPORT

(71) Applicant: Applied Materials, Inc., Santa Clara, CA (US)

(72) Inventors: Yogananda Sarode Vishwanath, Bangalore (IN); Xue Yang Chang, San Jose, CA (US)

(21) Appl. No.: 18/209,649

(22) Filed: Jun. 14, 2023

(51) Int. Cl. H01J 37/32; H01L 21/683; H01L 21/687

(52) U.S. Cl. CPC H01J 37/32724; H01J 37/32449; H01L 21/6833; H01L 21/68757; B33Y 30/00; H01J 2237/334

(57) ABSTRACT

Substrate support components including an integrally formed insulator body including a first surface and a second surface opposite the first surface, and a thickness of the insulator body exceeds an arcing threshold between the first body and the second body when the insulator body is arranged between a first electrically conductive body and a second electrically conductive body. The insulator body includes gas conduits within the insulator body and forming a gas flow path from the first surface to the second surface, including a gas conductance plug embedded within a first portion of the gas conduit and having at least a threshold gas conductance through the gas conductance plug, wherein the gas conductance plug obstructs an electrical discharge path between the first body and the second body when the insulator body is arranged with respect to the first body and the second body.

### TECHNICAL FIELD

This specification relates to semiconductor systems, processes, and equipment.

### BACKGROUND

Semiconductor fabrication can involve various processes performed on a substrate. These processes can take place in one or more processing chambers. For example, deposition processes can be performed to deposit layers of films of various materials on the substrate. In another example, plasma etching can be used in semiconductor processing to selectively etch one or more layers using a plasma formed from particular etching gas chemistries. Integrated circuits can be formed using semiconductor fabrication techniques from layer structures including multiple (e.g., two or more) layer compositions. As scaling of integrated circuits continues to move towards smaller features and increased aspect ratios, there is a growing need for precision fabrication of layer structures.

### SUMMARY

This specification describes technologies for substrate supports and related components. These technologies generally involve using additive manufacturing techniques to design and fabricate substrate supports and components thereof for use in substrate processing chambers.

As used in this specification, a substrate refers to a wafer or another carrier structure, e.g., a glass plate. A wafer can include a semiconductor material, e.g., Silicon, GaAs, InP, or another semiconductor-based wafer material. A wafer can include an insulator material, for example, silicon-on-insulator (SOI), diamond, etc. At times, the substrate includes film(s) formed on a surface of the wafer/carrier structure. The film(s) can be, for example, dielectric, conductive, or insulating films. The film(s) can be formed on the surface of the wafer using various deposition techniques, for example, spin-coating, atomic layer deposition (ALD), chemical vapor deposition (CVD), metal-organic chemical vapor deposition (MOCVD), molecular beam epitaxy (MBE), or other similar techniques for forming thin film layers on a wafer or another carrier structure. In some implementations, the fabrications tools described in this specification are plasma-based etching tools, where etch processes can be performed on the formed layers on the surface of the wafer/carrier structure and/or on the wafer.

In general, one innovative aspect of the subject matter described in this specification can be embodied in an integrally formed insulator body comprising a first surface and a second surface opposite the first surface, where the first surface is configured to retain a first body of the substrate support comprises an electrically conductive material, the second surface is configured to affix the insulator body to a second body of the substrate support, wherein the second body comprises an electrically conductive material, and a thickness of the insulator body exceeds an arcing threshold between the first body and the second body when the insulator body is arranged between the first body and the second body. The integrally formed insulator body includes one or more gas conduits within the insulator body extending from the first surface to the second surface and forming a gas flow path from the first surface to the second surface. Each of the one or more gas conduits includes a gas conductance plug embedded within a first portion of the gas conduit and having at least a threshold gas conductance through the gas conductance plug, and where the gas conductance plug obstructs an electrical discharge path between the first body and the second body when the insulator body is arranged with respect to the first body and the second body.

Other implementations of this aspect include corresponding methods of manufacture, data structures embodied in a machine-readable medium for designing, manufacturing, or testing a design, and corresponding systems, computer systems, apparatus, and computer programs recorded on one or more computer storage devices, each configured to perform the actions of the methods.

In general, another innovative aspect of the subject matter in this specification can be embodied in a conductor body including an edge portion and a center portion, where the conductor body is configured to support an electrostatic chuck on a first surface of the conductor body. The conductor body includes one or more cooling channels embedded within the conductor body and configured to facilitate coolant flow within at least one of the edge portion and the center portion of the conductor body. The one or more cooling channels include cooling fins, where the cooling fins include a first cross-section geometry oriented perpendicular to the coolant flow, and where the cooling fins include a second geometry having a threshold surface area parallel to the coolant flow. The conductor body includes a first gas conduit embedded in the conductor body configured to facilitate gas flow through the conductor body and couple into one or more second gas conduits of the electrostatic chuck, when the electrostatic chuck is supported by the first surface. The conductor body includes one or more isolation features integrally formed within the conductor body and oriented to reduce a threshold cross-talk between the edge portion of the conductor body and the center portion of the conductor body.

Other implementations of this aspect include corresponding methods of manufacture, and data structures embodied in a machine-readable medium for designing, manufacturing, or testing a design, and corresponding systems, computer systems, apparatus, and computer programs recorded on one or more computer storage devices, each configured to perform the actions of the methods.

The subject matter described in this specification can be implemented in these and other implementations so as to realize one or more of the following advantages. Using additive manufacturing (AM) techniques to manufacture substrate supports can overcome challenges in the methods to manufacture the substrate supports and components of the substrate supports, improve yield and increase complexity, as well as open up material possibilities. In one example, AM can be used to introduce features (e.g., complex shapes and/or internal geometries) otherwise unavailable or cost-prohibited by traditional, non-AM techniques, e.g., embedded sensors, complex internal channels/conduits, etc., Additionally, AM techniques can be used to introduce new material compositions, e.g., alloys, formed using powder composites in order to achieve desired material properties. For example, a ceramic/metallic blend of powders may be used to form a new material composition for AM-based components.

AM techniques can result in improved control over fidelity (e.g., defect reduction) of manufactured parts resulting in better performance of the manufactured parts, e.g., reduced helium leaks, improved capacitance, tighter (critical) dimensional control, reduced cracking due to machining, etc.

Additionally, AM techniques can be used to refurbish/regrow/modify existing substrate supports, which can result in increased lifetime of components and decreased costs by reusing rather than full replacement. The refurbishment/modification process can target localized degradation, e.g., due to use in a process environment and exposure to plasma and etch chemistries, in order to restore functionality of the substrate support for continued target performance and use. Localized AM-based regrowth techniques for refurbishment can reduce cost, material consumption, and time for the refurbishment. Additionally, refurbishments/modification can be used to update an existing component rather than fabricating a completely new component to incorporate a new feature.

Although the remaining disclosure will identify specific processes for etch-based fabrication tools using the disclosed technology, it will be readily understood that the systems and methods are equally applicable to a variety of other fabrication tools and chambers. Accordingly, the technology should not be considered to be so limited as for use with the described etching fabrication tools alone. The disclosure will discuss one possible system and chamber that can be used with the present technology before describing systems and methods or operations of exemplary process sequences according to some implementations of the present technology. It is to be understood that the technology is not limited to the equipment described, and processes discussed can be performed in any number of processing chambers and systems.

### BRIEF DESCRIPTION OF THE DRAWINGS

FIG. 1 shows a schematic cross-sectional view of an example plasma processing chamber.

FIG. 2 shows a schematic cross-sectional view of an example substrate support.

FIGS. 3A-3C show various schematic views of an example substrate support.

FIGS. 4A-4C show various schematic views of an example insulator body.

FIGS. 5A-5J show schematic cross-sectional views of example conductance plugs.

FIGS. 6A-6C show schematic cross-sectional views of portions of example insulator bodies.

FIGS. 7A-7C show various schematic views of an example conductor body.

FIGS. 8A-8F show cross-sectional views of example coolant channels.

FIG. 9 shows a cross-section view of an example coolant channel and thermal isolator.

FIG. 10A shows a schematic view of a portion of an example conductor body.

FIG. 10B shows a schematic view of a portion of an example conductor body.

FIG. 11 is a flow diagram of an example process for a substrate support.

FIG. 12 is a flow diagram of an example process for a substrate support.

FIG. 13 shows an example generic computer system.

Like reference numbers and designations in the various drawings indicate like elements.

### DETAILED DESCRIPTION

The present specification provides improved methods and assemblies for using additive manufacturing for fabricating a substrate support and/or components of the substrate support for use in substrate processing chambers. Implementations of the present disclosure include electrostatic chuck design enabled by additive manufacturing, where design parameters for the ESC can depend on design window of the additive manufacturing system and process.

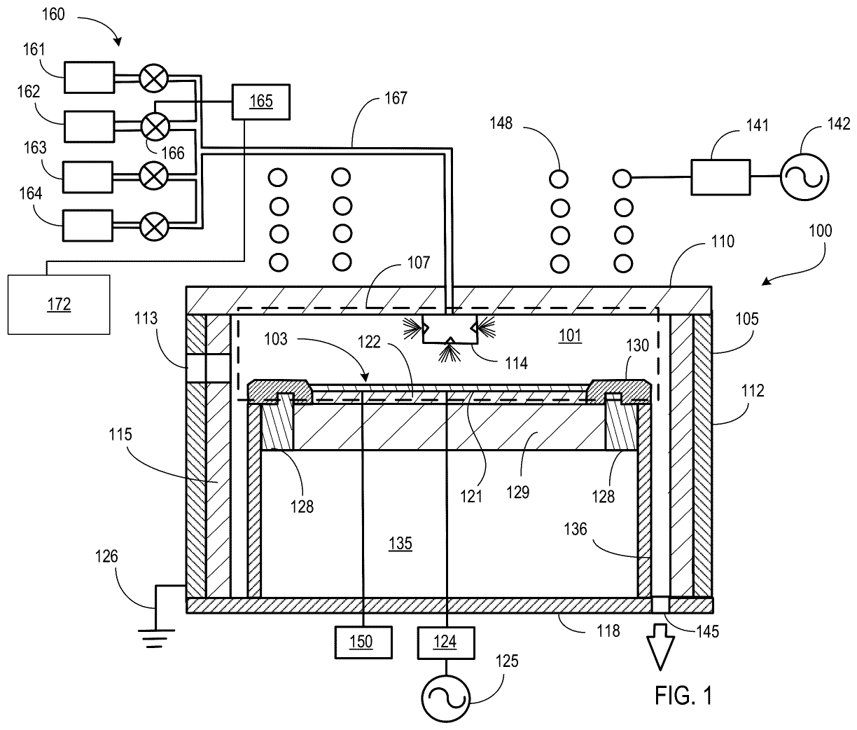

FIG. 1 illustrates a schematic cross-sectional view of an example processing chamber 100 suitable for etching one or more material layer(s) disposed on a substrate 103 (e.g., also referred to as a “wafer”) in the processing chamber 100, e.g., a plasma processing chamber. The processing chamber 100 includes a chamber body 105 defining a chamber volume 101 in which a substrate can be processed. The chamber body 105 has sidewalls 112 and a bottom 118 which are coupled with ground 126. The sidewalls 112 can include a liner 115 to protect the sidewalls 112 and extend the time between maintenance cycles of the plasma processing chamber 100. The chamber body 105 is supportive of a chamber lid assembly 110 to enclose the chamber volume 101. The chamber body 105 can be fabricated from, for example, ceramic, aluminum or other suitable materials. A substrate access port 113 is formed through the sidewall 112 of the chamber body 105, which can facilitate the transfer of the substrate 103 into and out of the plasma processing chamber 100. Access port 113 can be coupled with a transfer chamber and/or other chambers (not shown) of a substrate processing system, e.g., to perform other processes on the substrate. A pumping port 145 is formed through the bottom 118 of the chamber body 105 and connected to the chamber volume 101. A pumping device can be coupled through the pumping port 145 to the chamber volume 101 to evacuate and control the pressure within the processing volume. The pumping device can include one or more pumps and throttle valves.

Chamber volume 101 includes a processing region 107, e.g., a station for processing a substrate. A substrate support 135 can be disposed in the processing region 107 of chamber volume 101 to support the substrate 103 during processing. The substrate support 135 includes an electrostatic chuck 122 for holding the substrate 103 during processing. The electrostatic chuck (“ESC”) 122 can use electrostatic attraction to hold the substrate 103 to the substrate support 135. The ESC 122 can be powered by an RF or DC power supply 125 integrated with a match circuit 124. The ESC 122 can include an electrode 121 embedded within a dielectric body. The electrode 121 can be coupled with the RF or DC power supply 125 and can provide a bias which attracts plasma ions, formed from the process gases in the chamber volume 101, to the ESC 122 and substrate 103 seated on the pedestal. The RF or DC power supply 125 can cycle on and off, or pulse, during processing of the substrate 103. The ESC 122 can have an isolator 128 for the purpose of making the sidewall of the ESC 122 less attractive to the plasma to prolong the maintenance life cycle of the ESC 122. Additionally, the substrate support 135 can have a cathode liner 136 to protect the sidewalls of the substrate support 135 from the plasma and to extend the time between maintenance of the plasma processing chamber 100.

Electrode 121 can be coupled with a DC power source 150. The power source 150 can provide a chucking voltage of about 5000 volts to about-5000 volts to the electrode 121. The power source 150 can also include a system controller for controlling the operation of the electrode 121 by directing a DC current to the electrode 121 for chucking and de-chucking the substrate 103. The ESC 122 can include heaters disposed within the ceramic and connected to a power source for heating the substrate, while a cooling base 129 supporting the ESC 122 can include conduits for circulating a heat transfer fluid to maintain a temperature of the ESC 122 and substrate 103 disposed thereon. The ESC 122 can be configured to perform in the temperature range required by the thermal budget of the device being fabricated on the substrate 103. For example, the ESC 122 can be configured to maintain the substrate 103 at a temperature of about −150° C. or lower to about 500° C. or higher depending on the process being performed. A cover ring 130 can be disposed on the ESC 122 and along the periphery of the substrate support 135. The cover ring 130 can be configured to confine etching gases to a desired portion of the exposed top surface of the substrate 103, while shielding the top surface of the substrate support 135 from the plasma environment inside the plasma processing chamber 100.

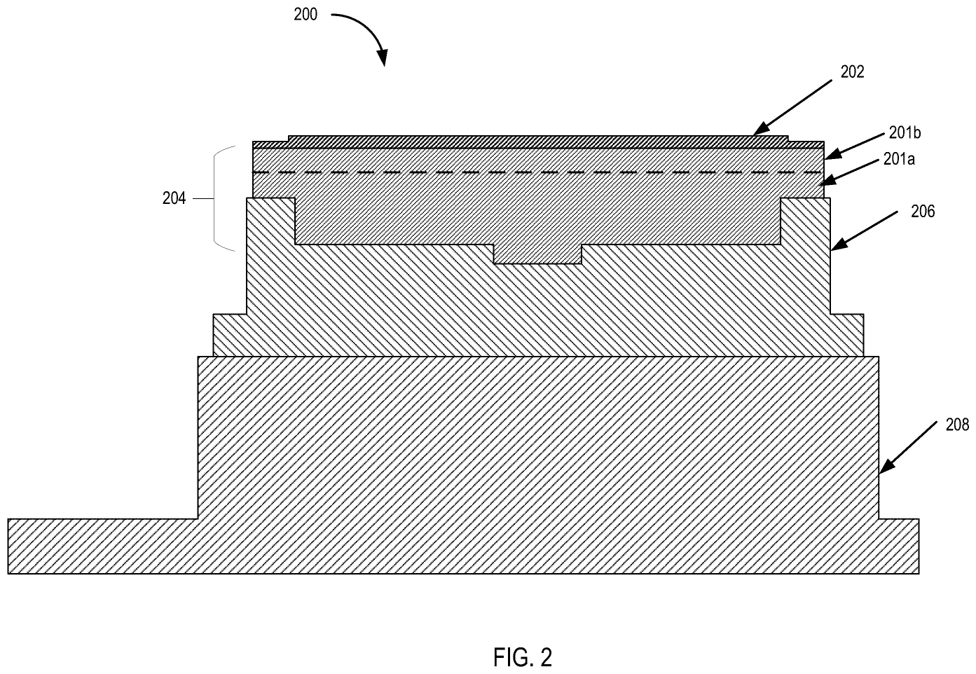

Substrate support 135 further includes a ground plate, an insulator body, a facilities plate, and a cooling base. FIG. 2 shows an example schematic view of a substrate support 200 including an ESC 202. In some implementations, the facilities plate 201a and cooling base 201b are formed as a unified structure (referred to herein as a “conductor body”). The conductor body 204 can be formed, for example, by additive manufacturing. The ground plate 208 can be formed of an electrically conductive material, e.g., a metal such as aluminum, and can be configured to be coupled to a bottom portion of the processing chamber 100. The ground plate can be secured to the processing chamber as well as to affix other components of the substrate support to the ground plate, e.g., the facilities plate or insulator body.

Insulator body 206 is formed of an insulating material, e.g., a polymeric material. The insulating material can include, for example, cross-linked polystyrene, polytetrafluoroethylene (PTFE), polyamide-imide (PAI), polyetheretherketone (PEEK), polyetherimide, polyphenylene sulfide (PPS), or a ceramic. A material of the insulator body can be selected based in part on an operating temperature of the fabrication processes (e.g., plasma etch processes), electrical properties, and/or radical compatibility (e.g., with plasma composition). A thickness of insulator body can be selected to reduce a thermal and electrical interaction (e.g., arcing) between the ground plate and the facilities plate/cooling base. Insulator body can be formed as a unified body, e.g., by additive manufacturing, where the insulator body can include internal geometries formed using additive manufacturing in a layer-by-layer process. Further details of the insulator body are described below.

The facilities plate 201a is coupled to the insulator and provides a pathway for connections (i.e., electrical, fluid, gas connections) to the cooling base and the ESC. The facilities plate and cooling base are formed from a metal, such as aluminum, molybdenum, stainless steel. A metal used for the cooling base can be selected, for example, based on a desired coefficient of thermal expansion (CTE) of the metal used in the cooling base and a CTE of a material used in the ESC, e.g., a threshold matching of CTEs may be desirable during a bonding/joining process of the cooling base and ESC. The cooling base is coupled to the facilities plate. The cooling base 201b includes a temperature control device embedded within the cooling base for controlling a temperature of the ESC, when the ESC is coupled to the cooling base. A temperature control device can include cooling channels for flowing coolant (e.g., water, ethylene glycol, or another coolant liquid) or a refrigerant, for example, depending in part on a specified temperature range for performing fabrication processes in the processing chamber. The cooling channels can be coupled to a heat exchange device (not shown) for controlling the temperature of the fluid. The temperature control device can include gas conduits for flowing gas (e.g., helium, nitrogen, or another gas) through the cooling base and into the ESC. A seal can be disposed around the periphery of cooling base and configured to prevent passage of a fluid between the cooling base and the facilities plate.

In some implementations, facilities plate and cooling base are formed as a unified structure, e.g., by additive manufacturing, where the combined conductor body 204 is an electrically and thermally conductive (conductor) body. The conductor body can be formed of an electrically and thermally conductive material in a layer-by-layer process and without requiring a seal around a periphery of the cooling base or bonding layer between the facilities plate and cooling base. For example, the material can be a metal such as aluminum or stainless steel, or a ceramic composite such as aluminum-silicon alloy, infiltrated SiC or Molybdenum. The conductor body is supported by the insulator body 206 and can be configured to couple connections (e.g., electrical, fluid, gas, etc.) into the components of the substrate support. The conductor body 204 is supportive of the ESC 202 and can include cooling channels, gas conduits, and electrical connections, one or more of which can couple into the ESC. Further details related to the conductor body are described below.

The substrate support 200 can include lift pins (not shown) disposed through openings formed in the substrate support. The lift pins can be coupled to actuators for raising and lowering the lift pins for positioning a substrate on the ESC.

Referring now to FIG. 1, a gas panel 160 (e.g., also referred to herein as “gas distribution manifold”) can be coupled by a gas line 167 with the chamber body 105 through chamber lid assembly 110 to supply process gases into the chamber volume 101. The gas panel 160 can include one or more process gas sources 161, 162, 163, 164 and can additionally include inert gases, non-reactive gases, and reactive gases, as can be used for any number of suitable processes. Examples of process gases that can be provided by the gas panel 160 include, but are not limited to, hydrocarbon containing gases including methane, sulfur hexafluoride, silicon chloride, silicon tetrachloride, carbon tetrafluoride, hydrogen bromide. Process gases that can be provided by the gas panel can include, but are limited to, argon gas, chlorine gas, nitrogen, helium, or oxygen gas, sulfur dioxide, as well as any number of additional materials. Additionally, process gasses can include nitrogen, chlorine, fluorine, oxygen, or hydrogen containing gases including, for example, BCl₃, C₂F₄, C₄F₈, C₄F₆, CHF₃, CH₂F₂, CH₃F, NF₃, NH₃, CO₂, SO₂, CO, N₂, NO₂, N₂O, and H₂, among any number of additional suitable precursors. Process gases from process gas sources, e.g., sources 161, 162, 163, 164, can be combined to form one or more etching gas mixtures. For example, gas panel 160 includes one or more process gas sources specific to oxide-based etching chemistries. In another example, gas panel 160 includes one or more process gas sources specific to nitride-based etching chemistries.

Gas panel 160 includes various valves, pressure regulators (not shown), and mass flow controllers (not shown) arranged with respect to the gas sources 161, 162, 163, 164 to control the flow of the process gases from the sources. Valves 166 can control the flow of the process gases from the sources 161, 162, 163, 164 from the gas panel 160. Operations of the valves, pressure regulators, and/or mass flow controllers can be controlled by a controller 165. Controller 165 can be operably coupled to an electro-valve (EV) manifold (not shown) to control actuation of one or more of the valves, pressure regulators, and/or mass flow controllers. The lid assembly 110 can include a gas delivery nozzle 114. The gas delivery nozzle 114 can include one or more openings for introducing the process gases from the sources 161, 162, 163, 164 of the gas panel 160 into the chamber volume 101. After the process gases are introduced into the plasma processing chamber 100, the gases can be energized to form a plasma. An antenna 148, such as one or more inductor coils, can be provided adjacent to the plasma processing chamber 100. An antenna power supply 142 can power the antenna 148 through a match circuit 141 to inductively couple energy, such as RF or DC energy, to the process gas to maintain a plasma formed from the process gas in the chamber volume 101 of the plasma processing chamber 100. Alternatively, or in addition to the antenna power supply 142, process electrodes below the substrate 103 and/or above the substrate 103 can be used to capacitively couple RF or DC power to the process gases to maintain the plasma within the chamber volume 101. The operation of the power supply 142 can be controlled by a controller, such as controller 165, that also controls the operation of other components in the plasma processing chamber 100.

The controller 165 can be used to control the process sequence, regulating the gas flows from the gas panel 160 into the plasma processing chamber 100, and other process parameters. Software routines, when executed by a computing device having one or more processors (e.g., a central processing unit (CPU)) in data communication with one or more memory storage devices, transform the computing device into a specific purpose computer such as a controller, which can control the plasma processing chamber 100 such that the processes are performed in accordance with the present disclosure. The software routines can also be stored and/or executed by one or more other controller(s) that can be associated with the plasma processing chamber 100.

In some implementations, controller 165 is in data communication with a characterization device 172. Characterization device 172 can include one or more sensors (e.g., image sensors) operable to collect processing data related to processing chamber 100. For example, characterization device 172 includes an optical emission spectroscopy device configured to monitor a signal, e.g., emitted light of a plasma, within a processing region of the processing chamber 100. For example, a signal can be a primary or highest intensity wavelength of emitted light. Characteristics of the emitted light (e.g., wavelength and intensity) from the plasma within the processing region can depend in part on an etching gas mixture used to generate the plasma as well as a layer composition of the layer being etched. For example, each etching gas mixture and corresponding layer composition being etched can have a respective signal signature. Emitted wavelengths that are unique or distinguishing for each etching gas mixture and corresponding layer composition can be monitored to determine an etching condition of the layer being etched. For example, a thickness remaining of the layer being etched. Characteristics of the emitted light from the plasma can change, e.g., based on the etching process. For example, an intensity of a monitored signal can change as material is removed from the layer being processed. Characterization device 172 can be configured to collect processing data including the respective signals corresponding to the etching gas mixtures utilized in the wafer processing and corresponding layer compositions of the structure being processed in the processing chamber 100. Controller 165 can receive processing data from the characterization device 172 and determine, from the processing data, one or more actions to perform.

In some implementations, at a termination point of etching process(es) for the wafer, an automatic or semi-automatic robotic manipulator (not shown) can be utilized to transfer the wafer(s) from the substrate support out of the process chamber, e.g., through substrate access port 113. For example, the robotic manipulator can transfer the wafer to another chamber (or another location) to perform another step in a fabrication process.

In some implementations, a controller (e.g., controller 165) of a fabrication tool can execute a recipe including instructions for a fabrication process. The recipe can include temperature-control instructions executable by the controller 165 to control operations of various temperature-related components of the fabrication tool. For example, the temperature-related components can include (A) gas pressures introduced into each of the cooling regions of the ESC, (B) temperature settings for each of the multiple heaters with respective heating zones within the ceramic body of the ESC, (C) temperature settings for each of the microzone heaters within the ceramic body of the ESC, (D) coolant flow into cooling channels located in a base of the substrate support, or (E) any combination thereof. The recipe instructions can additionally include executable instructions related to other process parameters in addition to the operations of the ESC to operate components of the fabrication tool to control, for example, plasma power, flow of the etch gas, etc.

In some implementations, substrate support design can be selected to improve substrate processing including adapting various design parameters for the substrate support. Relationships between the various design parameters in a substrate support design can be complex, where a design parameter may affect one or more other design parameters. Adapting the various design parameters into a design can yield a unique solution for a substrate support to improve process uniformity (e.g., temperature uniformity) during a fabrication process. Moreover, as discussed in further detail below, AM techniques can be used instead of, or in addition to, traditional, non-AM manufacturing techniques to expand a design window of what fabricated designs are possible to implement.

### AM-Based Insulator Body

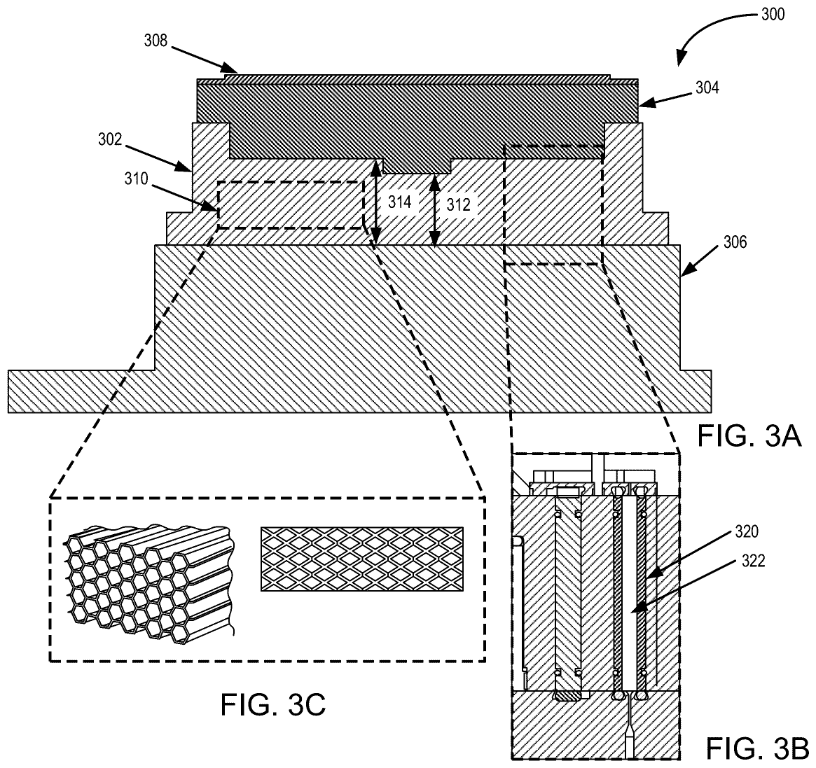

In some implementations, additive manufacturing (e.g., 3D printing) processes can be used to facilitate a design space for an insulator body of the substrate support, e.g., insulator body 206. As depicted in FIGS. 3A-3C, various subcomponents of the insulator body can be enabled by additive manufacturing techniques, one or more of which may not be otherwise achievable by traditional manufacturing techniques. FIG. 3A shows a schematic cross section of an example substrate support 300 including an insulator body 302, conductor body 304, ground plate 306 and ESC 308. The insulator body 302 can include embedded regions within the insulator body, e.g., region 310, having internal geometries. Characteristics of the embedded regions can be selected to have at least a threshold impedance between the radio-frequency (RF) hot (e.g., voltage biased) components and grounded components of the substrate support as well as a threshold internal structural strength. For example, the internal geometries can have a selected threshold impedance based in part on a creepage path between the RF hot portions of the substrate support and ground during operation of the processing chamber. Characteristics of the embedded regions can include, for example, a ratio between volumes of the insulating material and the volumes without insulating material (air, vacuum, or gas filled), patterns of the internal geometries, or the like.

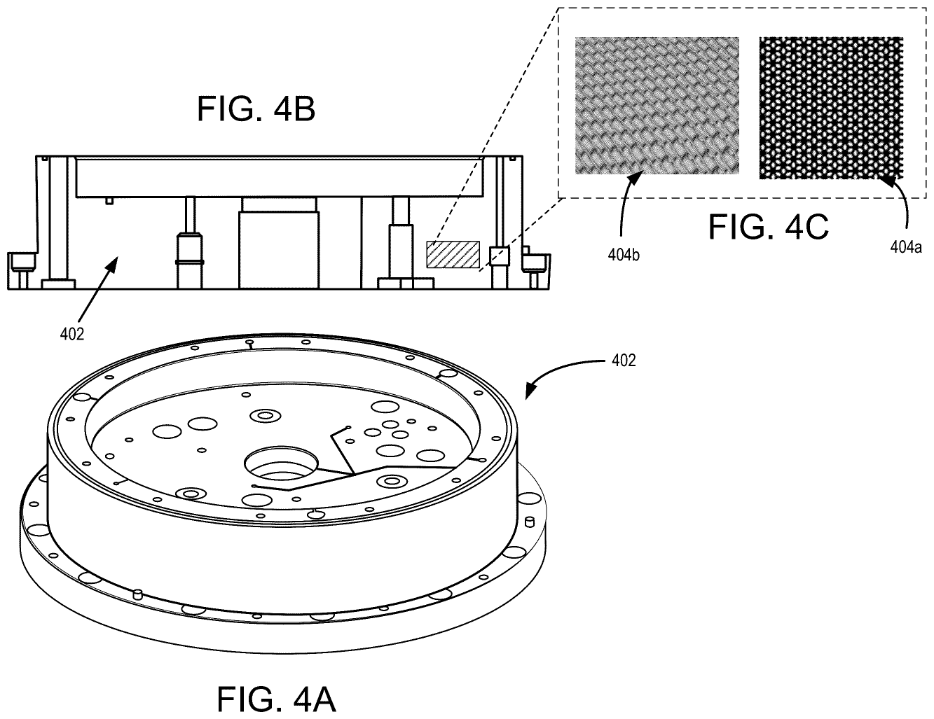

In some implementations, internal geometries of the insulator body 302 can be 3D printed lattice patterns. FIGS. 3C, 4C depict examples of the internal geometries, e.g., honeycomb, cross-beam, gyroid, etc. The regions including internal geometries can reduce material costs while retaining the required functionality of the insulator body.

In some implementations, dimensions of the insulator body 302 can be selected based in part on a creepage path between RF hot components and grounded components of the support structure, e.g., between the conductor body 304 (e.g., facility plate and cooling base) and the ESC 308 and the ground plate. One or more creepage paths can exist between a conductor body 304 in contact with a first surface of the insulator body 302 and a ground plate 306 in contact with a second surface of the insulator body 302. An insulator body 304 can include two or more creepage paths between, based on a geometry of the insulator body. For example, a substrate support 300 can have at least a first creepage path 312 and a second creepage path 314 between the conductor body 304 and ground plate 306 during operation of the processing chamber. A minimum thickness of the insulator body can be selected to be equal to or greater than the creepage path.

In some implementations, thickness of the insulator body 302 along a creepage path, e.g., creepage path 312, can be scaled by about 3.175 cm of insulating material thickness per 10 kV of voltage difference between RF hot components and grounded components of the substrate support. The thickness of insulating material can provide at least a threshold impedance during operation of the processing chamber and reduce a likelihood of arcing between the RF hot and grounded components. For example, for a 16 kV bias voltage between the RF hot components and grounded components, a creepage path can be greater than about 5 cm such that a thickness of insulating material along the creepage path is needed to (substantially) prevent arcing.

In some implementations, additive manufacturing techniques can be used to form the insulator body as an integral body (e.g., in a layer-by-layer process) and without requiring multiple separately formed sheets of insulating material to be affixed together, for example, as depicted in FIGS. 4A and 4B. FIGS. 4A and 4B show various views of an insulator body 402 formed as an integral body using AM techniques. FIG. 4C depicts two example structures for internal geometries 404a, 404b which form at least a portion of the insulator body 402. AM techniques can facilitate forming regions of internal geometries, e.g., as depicted in FIGS. 3C, 4C, which may otherwise be unattainable by conventional manufacturing techniques.

The insulator body of the substrate support includes one or more gas conduits to facilitate gas flow through the insulator body and into other components of the substrate support, e.g., into the conductor body (facilities plate and cooling base) and ESC. FIG. 3B depicts an example schematic view of gas conduits 320 for gas flow through the insulator body 302. A gas conduit 320 includes a gas conductance plug 322, e.g., a porous plug, that obstructs an electrical discharge path between an RF hot portion of the substrate support and a grounded portion of the substrate support, e.g., between a facilities plate and ground plate, while still allowing a specified gas flow rate through the gas conduit 320.

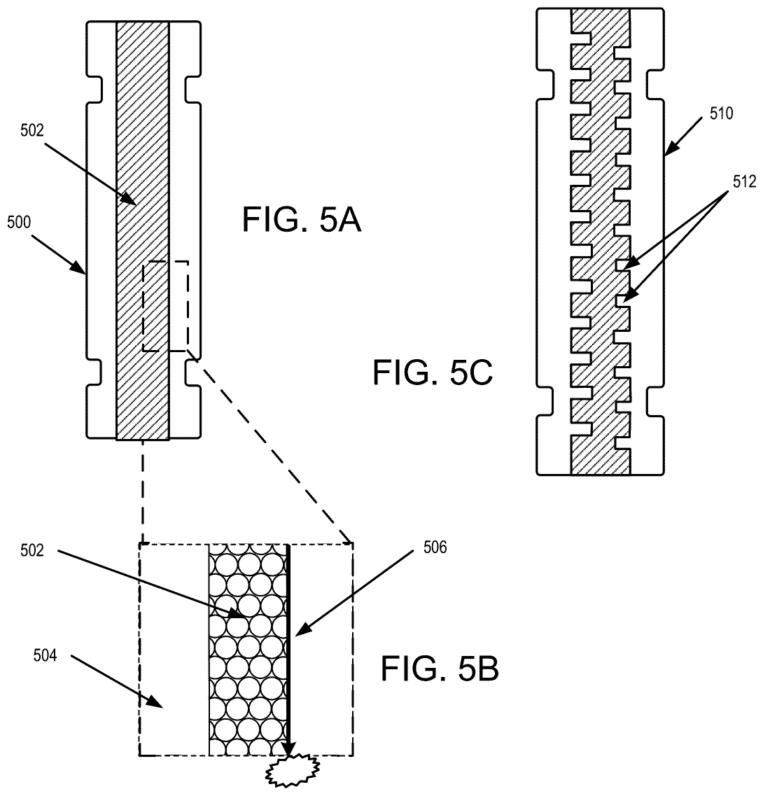

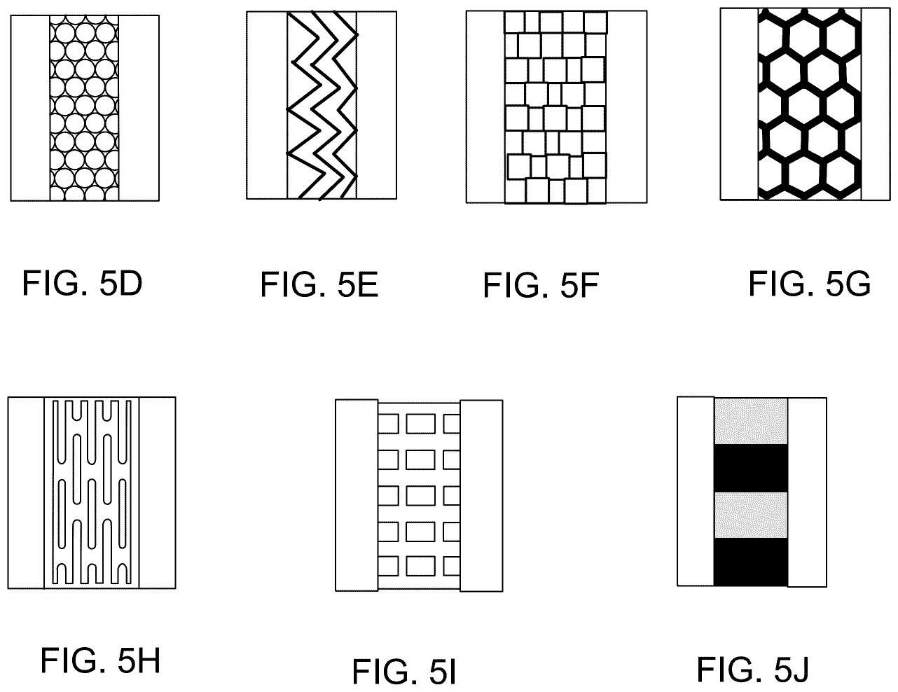

FIGS. 5A-5J show example schematic views of various gas conductance plug designs. As depicted in the cross-sectional views of FIGS. 5A and 5B, a portion 502 of the gas conductance plug 500 is formed of a porous material, e.g., ceramic material, to facilitate a flow of gas (e.g., helium) but can prevent a backflow of other gases, contaminants, etc., through the gas conductance plug. The gas conductance plug includes an outer ceramic portion 504. The gas conductance plug can obstruct (e.g., prevent, substantially reduce) an electrical discharge path 506 through the gas conduit to prevent arcing within the process chamber to the ground plate. Gas conductance plug can obstruct a line-of-sight from an electrically charged (e.g., RF hot) facilities plate to ground but maximize a gas flow through the plug. For example, as depicted in FIG. 5C, gas conductance plug 510 can include internal features 512 that create a convoluted gas flow path and obstruct line-of-sight of an electrical arc path. A gas conductance plug defines a convoluted gas flow path having a gas conductance from one end of the gas conductance plug to a second end of the gas conductance plug. The convoluted path can define a longest gas flow path for a given gas flow rate. For example, a higher flow gas conductance plug can provide a higher helium pressure to the ESC, e.g., for low temperature substrate applications.

In some implementations, additive manufacturing (AM) techniques can be used to form one or more features and/or components of the insulator body. For example, AM techniques can be used to form the gas conductance plugs from a same or different material than the surrounding insulator body. In another example, AM techniques can be used to form gas conductance plug that are integrally formed with the insulator body. A desired gas flow through a gas conduit can be selected during a design process for an AM formed insulator body based on internal structure of the gas conduit, e.g., of the gas conductance plug. For example, the features (e.g., gas conductance plugs, outer/inner sleeves, etc.) of the gas conduits can be formed using AM techniques to have a different gas flow, e.g., a higher gas flow, than gas conduits facilitating gas flow to an inner cooling zone of the ESC. Generally, AM techniques can be used to rapidly design and deploy different designs for the gas conductance plugs.

In some implementations, AM techniques can be used to form a gas conductance plug that substantially reduces or eliminates a radial gap between a porous center portion of the gas conductance plug and a ceramic sleeve surrounding the porous center portion. Reducing or eliminating the radial gap can obstruct a potential arcing path through the radial gap.

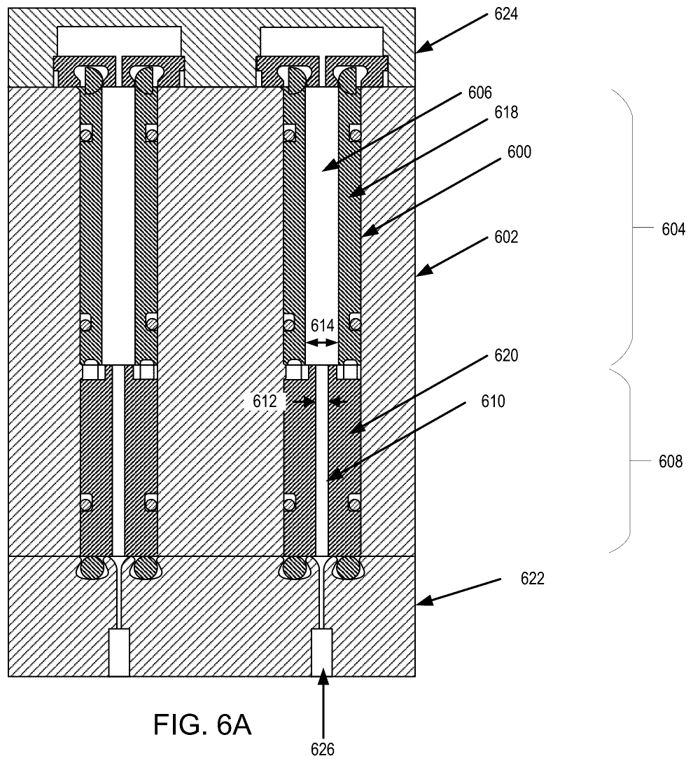

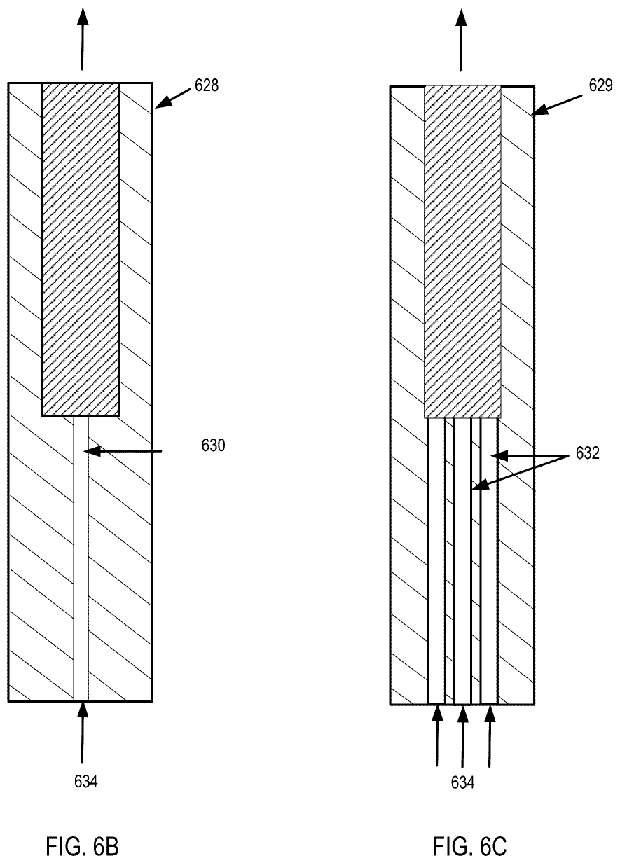

In some implementations, different gas conduits embedded in the insulator body can include different gas conductance plug designs to tune a respective gas flow through each of the different gas conduits. FIG. 6A shows an example schematic view of a gas conduit including gas conductance plugs. In some implementations, a gas conduit 600 within insulator body 602 includes a first portion 604 including a gas conductance plug 606 having a first diameter associated with the porous material and a second portion 608 including gas conduit 610 having a second diameter. A diameter 612 of the gas conduit 610 can be smaller than a diameter 614 of the gas conductance plug. The gas conduit 610 can facilitate flow of gas from a ground plate 622 to a first surface of the gas conductance plug 606. The first portion 604 of gas conduit 600 includes an outer sleeve 618 surrounding the gas conductance plug 606. The second portion 608 of gas conduit 600 includes a ceramic portion 620 surrounding gas conduit 610. Gas conduit 600 extends from a first surface of the insulator body 602 in contact with the ground plate 622 to a second surface of the insulator body 602 in contact with the conductor body 624 (e.g., facilities plate and cooling base). The gas conduit 600 facilitates a gas flow 626 from the ground plate 622 through the insulator body 602 and into the conductor body 624.

In some implementations, a gas flow path through the insulator body can include one or more gas conduits. FIGS. 6B and 6C show example schematic views of gas flow paths including gas conductance plugs. A gas flow path 628 can include one gas flow conduit, e.g., gas conduit 630 as depicted in FIG. 6B, or a gas flow path 629 can include two or more gas conduits, e.g., three gas conduits 632 as depicted in FIG. 6C. A number of gas conduits can be selected to adjust a gas flow 634 through the gas conductance plug of the gas flow path. For example, a larger number of gas conduits can facilitate a higher gas flow through the gas conductance plug than a smaller number of gas conduits.

### AM-Based Conductor Body

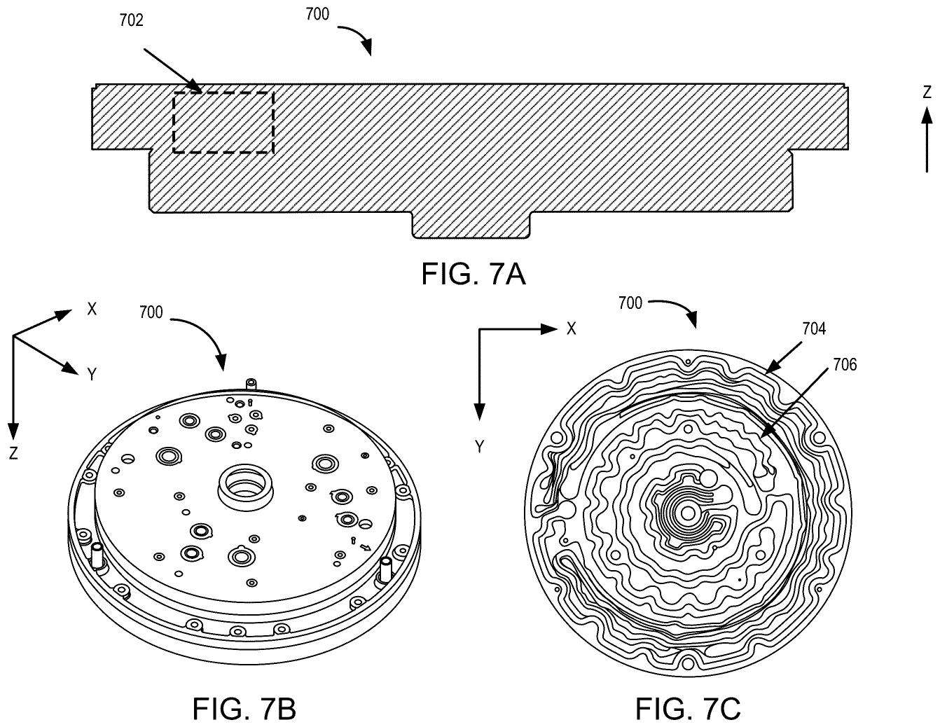

In some implementations, additive manufacturing (e.g., 3D printing) processes can be used to facilitate a design space for manufacturing a unified facilities plate and cooling base as an integral (e.g., unified) body, e.g., referred to here as a “conductor body” or “conductive body.” As depicted in FIGS. 7A-7C, various subcomponents and/or integrated and/or embedded features of the conductor body can be enabled by additive manufacturing techniques, one or more of which may not be otherwise achievable by traditional manufacturing techniques.

An integrally formed conductor body, including the functionality of the facilities plate and cooling base as described with reference to FIG. 1, can reduce fabrication steps which can result in reduced leaking/failure points in the support structure. For example, features of the facilities plate and cooling base which would otherwise require vacuum brazing between components of the cooling base and/or e-beam welding of cooling channels can be formed instead using AM techniques. Moreover, using AM techniques to form an integral conductor body can reduce the need for seals, e.g., O-ring seals, gaskets, and fixtures, e.g., dowel pins, screws, fixtures etc., required to affix subcomponents of the substrate support together. An integrally formed conductor body can have improved electrical RF performance and/or thermal performance in comparison to two or more subcomponents affixed together, e.g., by reducing a number of interfaces and welded/brazed unions.

In some implementations, as depicted in FIGS. 7A-7C, an integrally formed conductor body 700 can include features embedded 702 within the body of the conductor body. As depicted in FIGS. 7B and 7C, features of the conductor body for example, channels, gas conduits, isolation features, electrical connections, through-holes, etc., can be formed during an AM process and without requiring welding/brazing steps, as described in further detail below. Additionally, a complexity of the internal structures can be increased using AM techniques in comparison to traditional forms of manufacturing. FIG. 7C shows a schematic view of complex cooling channels for an edge portion 704 and cooling channels for a center portion 706 embedded within the conductor body 700 which can be formed in a layer-by-layer process using additive manufacturing techniques.

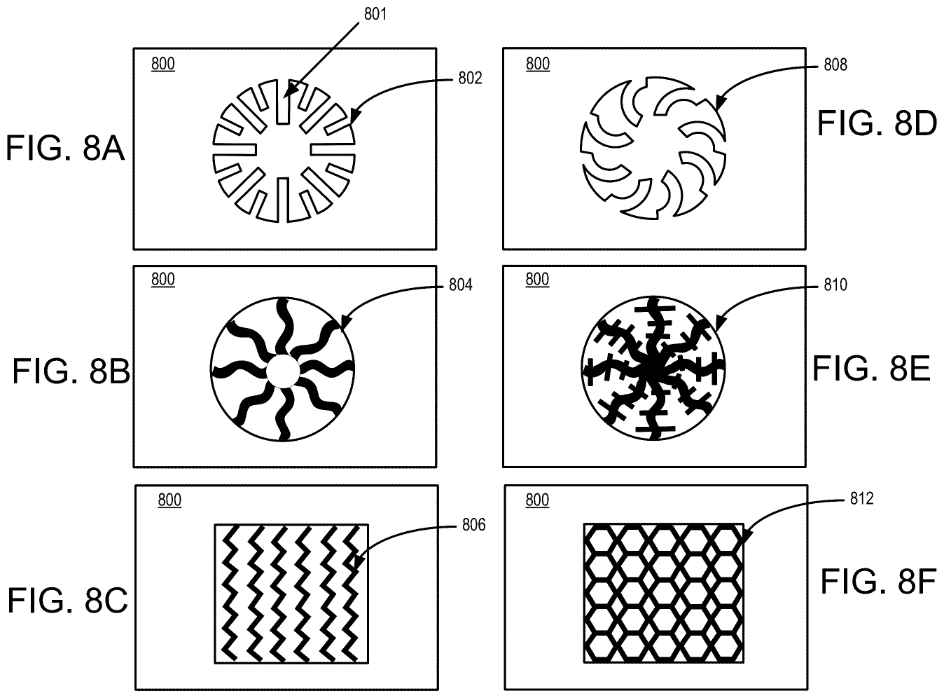

In some implementations, a conductor body includes cooling channels having internal features, e.g., cooling fins. FIGS. 8A-8F show example cross-sectional schematic views of various cooling channels 802, 804, 806, 808, 810, 812 integrally formed in a conductor body 800. The cooling fins, e.g., cooling fin 801, can include a first cross-sectional geometry (perpendicular to flow of coolant) and a second geometry (parallel to a flow of coolant). Although several different geometries are depicted in FIGS. 8A-8F, generally, the geometry of the cooling fins parallel to the flow of the coolant can be selected to achieve at least a threshold (e.g., optimize) amount of heat exchange between the cooling fins and the coolant as the coolant flows through the cooling channel. Multiple different cooling fin geometries can be utilized to improve heat transfer efficiency in multiple different regions of the conductor body. The geometry of the cooling channels can be selected such that the cooling mechanism is contact-dominated by an exposed surface area of the cooling fins within the cooling channels.

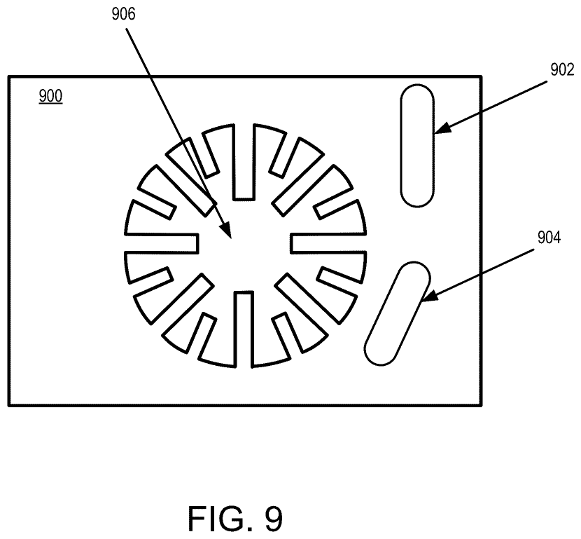

In some implementations, an integrally formed conductor body can include isolation features embedded within the conductor body and formed integrally with the conductor body, e.g., by additive manufacturing. FIG. 9 shows an example schematic view of isolation features 902, 904 embedded within a conductor body 900. The isolation features 902, 904 can be arranged within the body of the conductor body 900 and with respect to the cooling channels 906. An isolation feature can be, for example, a thermal isolation feature configured to reduce thermal cross-talk between regions of the conductor body. For example, a thermal break or a thermal choke. Thermal isolation features can be used, for example, to improve center-to-edge temperature uniformity (e.g., tunability). In another example, an isolation feature can be a capacitance isolation feature. Thermal isolation features can also be used to reduce a thermal mass of the conductor body, yield improved thermal response.

In some implementations, using additive manufacturing techniques, isolation features can be formed integrally and can be embedded within the conductor body, without requiring additional manufacturing steps (e.g., subtractive manufacturing).

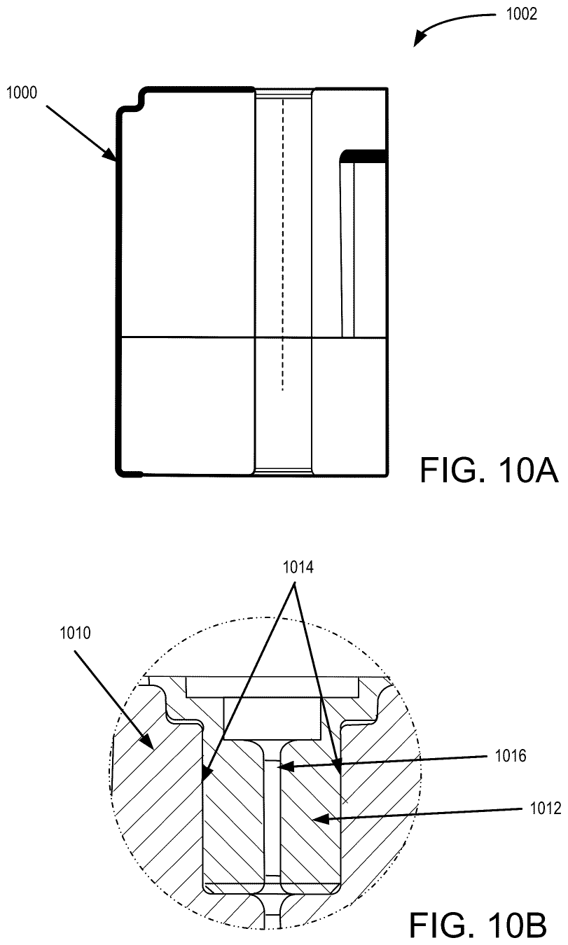

In some implementations, a portion of the substrate support can be coated with a protective coating, e.g., as depicted in FIG. 10A. The protective coating 1000 can be applied to surfaces that are exposed to the plasma during fabrication processes, e.g., to an exposed surface of the conductor body 1002. Protective coating can be a ceramic coating having anti-arcing properties. Ceramic coating can be made of, for example, alumina. The protective coating can be formed on a surface of the substrate support, using additive manufacturing techniques (e.g., using plasma spray coating).

In some implementations, integrated features of the conductor body enabled by additive manufacturing techniques includes forming the conductor body from two or more different materials. As depicted in FIG. 10B, conductor body 1010 can include a 3D printed ceramic insulator 1012 (e.g., alumina insulator) integrated into the conductor body for gas conduits 1016. By using additive manufacturing techniques to form integral bodies using different materials, bonding 1014 between subcomponents of different materials can be eliminated.

In some implementations, additive manufacturing e.g., three-dimensional printing (or 3-D printing), may be used to produce (or make) the substrate support and components described herein. In one embodiment, a computer (CAD) model of the required part is first made and then a slicing algorithm maps the information for every layer. A layer starts off with a thin distribution of powder spread over the surface of a powder bed. A chosen binder material then selectively joins particles where the object is to be formed. Then a piston which supports the powder bed and the part-in-progress is lowered in order for the next powder layer to be formed. After each layer, the same process is repeated followed by a final heat treatment to make the object. Since 3-D printing can exercise local control over the material composition, microstructure, and surface texture, various (and previously inaccessible) geometries may be achieved with this method.

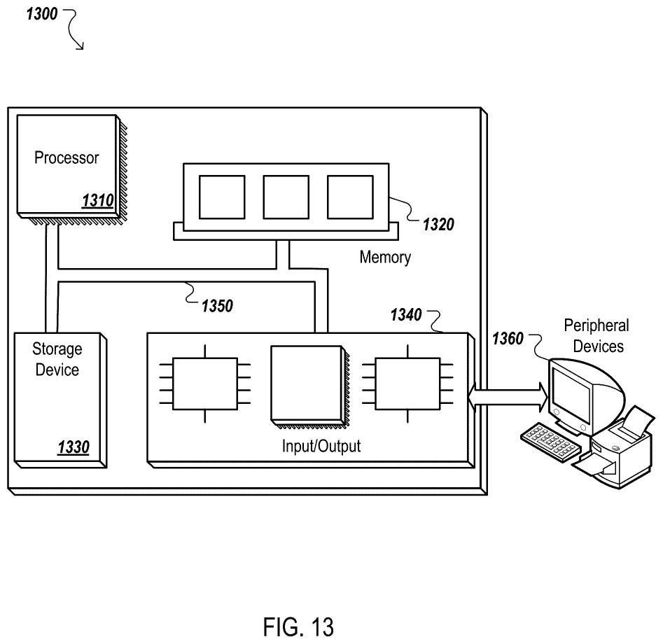

In one embodiment, a substrate support and components of a substrate support as described herein may be represented in a data structure readable by a computer rendering device or a computer display device. FIG. 13 is a schematic representation of a computer system with a computer-readable medium according to one embodiment. The computer-readable medium may contain a data structure that represents one or more components of the substrate support, e.g., a conductor body, isolator body, ESC, etc. The data structure may be a computer file, and may contain information about the structures, materials, textures, physical properties, or other characteristics of one or more articles. The data structure may also contain code, such as computer executable code or device control code that engages selected functionality of a computer rendering device or a computer display device. The data structure may be stored on the computer-readable medium. The computer readable medium may include a physical storage medium such as a magnetic memory, floppy disk, or any convenient physical storage medium. The physical storage medium may be readable by the computer system to render the article represented by the data structure on a computer screen or a physical rendering device which may be an additive manufacturing device, such as a 3D printer.

In some implementations, additive manufacturing techniques can be used in combination with other manufacturing techniques, e.g., subtractive manufacturing. For example, subtractive manufacturing can be used to modify/remove portions of the substrate support and additive manufacturing can be used to add/modify portions of the substrate support. The combination of techniques can be used during the initial process to manufacture or to modify/refurbish/regrow an existing substrate support or components of a substrate support to repair damage or change a configuration of the features.

In some implementations, additive manufacturing techniques can be used to regrow/refurbish portions of a substrate support, e.g., to repair operational damage or manufacturing damage, and/or to add features.

In some implementations, additive manufacturing techniques can be used to form the substrate support and/or components of the processing chamber using two or more material compositions, e.g., simultaneously or sequentially. Different material compositions can include, for example, AlN and Al₂O₃. Different material compositions can include, for example, different porosity or another material structural difference of a same material composition. For example, porous plugs can be formed of a different material composition (or having a different material structure of the same material composition) than the insulator material of the substrate support. Different materials can include, for example, ceramic materials and metallic materials, e.g., AlN and Aluminum.

In some implementations, additive manufacturing techniques can include ceramic-based additive manufacturing including a binder, e.g., a polymer binder, to form a slurry including a ceramic powder and where a photosensitizer can be included in the slurry that is sensitized (e.g., is curable by) to a wavelength of light. For example, a photopolymerization technique using ultraviolet (UV) light can be used to form a ceramic green body, which can then be consolidated into a ceramic part from the green body using a sintering process.

In some implementations, additive manufacturing techniques can include coating process, where layers of a body are formed in a layer-by-layer process using coating techniques, e.g., plasma spray coating, screen printing, etc. Plasma spray coating process can be used to coat an exposed surface from a powder, e.g., a ceramic powder, metal powder, or a combination of ceramic and metallic powder. Screen printing can be used to form, for example, metal-based electrodes as described in this specification.

In some implementations a sintering (e.g., firing) process can be used to consolidate the ceramic powder/particles (e.g., remove porosity and densify the ceramic material) of a green state ceramic part. For example, a sintering process can be performed at a high temperature below a melting point of the ceramic material(s) where the material of the separate particles diffuse towards neighboring power particles to form a densified ceramic body. In some implementations, the sintering process includes a pre-heat process to remove organic materials, e.g., polymer(s), lubricant, binders, etc. In some implementations, the sintering process includes a cooling process to cool down the ceramic parts to reduce cracking/stress formation.

In some implementations, a rapid sintering process, e.g., a flash sintering process, can be performed on set of green ceramic layers of a green ceramic body. For example, a sintering process can be alternated with a forming/AM process, where a set number of layers are formed by AM and then sintered in sequence before another set of layers are formed by AM on the exposed surface of the body. In other words, portions of the ceramic body are formed in a green state and sintered in succession, where an end result of the process is a densified ceramic body.

In some implementations, a refurbished part can be sintered such that the regrown layers of the refurbishing process are densified, e.g., to match characteristics of the original part.

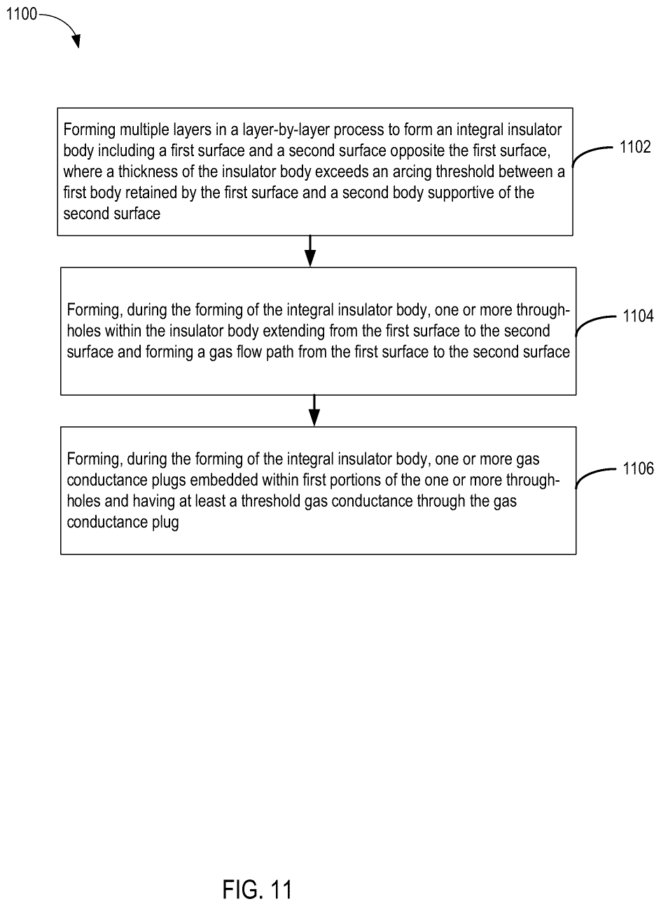

FIG. 11 is a flow diagram of an example process 1100 for manufacturing a substrate support component for substrate processing. For convenience, process 1100 will be described with respect to an additive manufacturing system that performs at least some steps of the process.

An additive manufacturing system forms multiple layers in a layer-by-layer process to form an integral insulator body including a first surface and a second surface opposite the first surface, where a thickness of the insulator body exceeds an arcing threshold between a first body retained by the first surface and a second body supportive of the second surface (1102). The additive manufacturing system can receive, from a computer system, a data structure representative of the insulator body, and use the data structure to form the multiple layers of the insulator body. The insulator body, e.g., insulator body 302, can include one or more thicknesses, e.g., 312 and 314, between the first body and the second body, each thickness being at least a threshold thickness based on a respective creepage path. The insulator body can be formed as a unified structure, e.g., without needing fixtures or other attachment features to affix two or more separate insulator sub-components together to form the insulator body.

The additive manufacturing system forms, during the forming of the integral insulator body, multiple layers including one or more gas conduits within the insulator body extending from the first surface to the second surface and forming a gas flow path from the first surface to the second surface (1104). The one or more gas conduits, e.g., gas conduit 320, can be formed during the AM process of forming the insulator body, e.g., where features are embedded in the layer-by-layer process according to the data structure representative of the insulator body used by the additive manufacturing system to form the features.

The additive manufacturing system forms, during the forming of the integral insulator body, multiple layers including one or more gas conductance plugs embedded within first portions of the one or more gas conduits and having at least a threshold gas conductance through the gas conductance plug (1106). Each of the gas conductance plugs, e.g., gas conductance plugs depicted in FIGS. 5A-5J, can be made of a different material composition (e.g., a different ceramic) and/or having different structural characteristics than the ceramic body (e.g., a different porosity, internal structure). The forming of the layers including the gas conductance plug can include additive manufacturing techniques including forming the layer include two different material compositions simultaneously or sequentially.

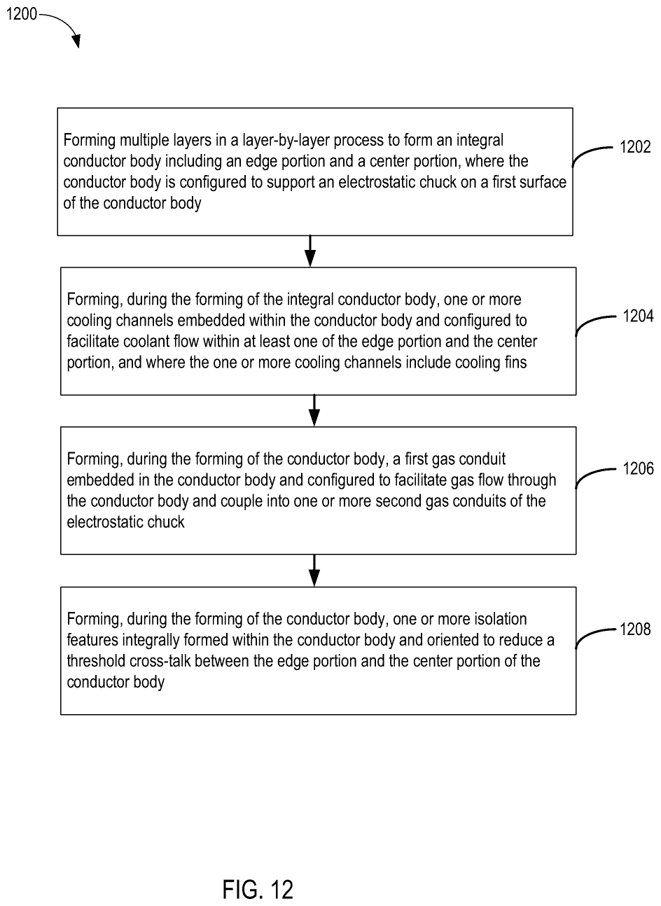

FIG. 12 is a flow diagram of an example process 1200 for forming a substrate support component using additive manufacturing. For convenience, process 1200 will be described with respect to an additive manufacturing system that performs at least some steps of the process.

An additive manufacturing system forms multiple layers in a layer-by-layer process to form an integral conductor body including an edge portion and a center portion, where the conductor body is configured to support an electrostatic chuck on a first surface of the conductor body (1202). The additive manufacturing system can receive, from a computer system, a data structure representative of the conductor body, and use the data structure to form the multiple layers of the conductor body. The conductor body, e.g., conductor body 700, can be formed as a unified structure, e.g., without needing fixtures or other attachment features to affix two or more separate sub-components (e.g., a facilities plate and a cooling base) together to form the conductor body. One or more features, e.g., cooling channels, gas conduits, and/or isolation features, can be formed during the AM process of forming the conductor body, e.g., where features are embedded in the layer-by-layer process according to the data structure representative of the conductor body used by the additive manufacturing system to form the features.

The additive manufacturing system forms, during the forming the integral conductor body, one or more cooling channels embedded within the conductor body and configured to facilitate coolant flow within at least one of the edge portion and the center portion, and where the one or more cooling channels include cooling fins (1204). Cooling channels, e.g., cooling channels 704 for an edge portion and cooling channels 706 for a center portion of conductor body 700, can have complex internal structures including cooling fins, e.g., cooling fins 801 of cooling channel 802.

The additive manufacturing system forms, during the forming the integral conductor body, a first gas conduit embedded in the conductor body and configured to facilitate gas flow through the conductor body and couple into one or more second gas conduits of the electrostatic chuck (1206). Gas conduits, e.g., gas conduit 1016, can be embedded in the conductor body including a ceramic isolator, e.g., ceramic isolator 1012. The ceramic isolator can be formed during the AM process, e.g., by depositing ceramic material in particular locations according to the data structure for the conductor body.

The additive manufacturing system forms, during the forming the integral conductor body, one or more isolation features integrally formed within the conductor body and oriented to reduce a threshold cross-talk between the edge portion and the center portion of the conductor body (1208). Isolation features, e.g., isolation features 902, 904, can be formed during the AM process to form the conductor body to reduce a cross-talk between an edge portion and a center portion of the conductor body, e.g., to improve thermal uniformity across the conductor body and, consequently, thermal uniformity across an ESC affixed to the conductor body and substrate retained by the ESC during a fabrication process.

FIG. 13 is a block diagram of an example computer system 1300 that can be used to perform operations described above. For example, such as operations performed by the controller 165. The system 1300 includes a processor 1310, a memory 1320, a storage device 1330, and an input/output device 1340. Each of the components 1310, 1320, 1330, and 1340 can be interconnected, for example, using a system bus 1350. The processor 1310 is capable of processing instructions for execution within the system 1300. In one implementation, the processor 1310 is a single-threaded processor. In another implementation, the processor 1310 is a multi-threaded processor. The processor 1310 is capable of processing instructions stored in the memory 1320 or on the storage device 1330.

The memory 1320 stores information within the system 1300. In one implementation, the memory 1320 is a computer-readable medium. In one implementation, the memory 1320 is a volatile memory unit. In another implementation, the memory 1320 is a non-volatile memory unit.

The storage device 1330 is capable of providing mass storage for the system 1300. In one implementation, the storage device 1330 is a computer-readable medium. In various different implementations, the storage device 1330 can include, for example, a hard disk device, an optical disk device, a storage device that is shared over a network by multiple computing devices (e.g., a cloud storage device), or some other large capacity storage device.

The input/output device 1340 provides input/output operations for the system 1300. In one implementation, the input/output device 1340 can include one or more of a network interface device, e.g., an Ethernet card, a serial communication device, e.g., and RS-232 port, and/or a wireless interface device, e.g., and 802.11 card. In another implementation, the input/output device can include driver devices configured to receive input data and send output data to peripheral devices 1360, e.g., keyboard, printer and display devices. Other implementations, however, can also be used, such as mobile computing devices, mobile communication devices, set-top box television client devices, etc.

Although an example processing system has been described in FIG. 13, implementations of the subject matter and the functional operations described in this specification can be implemented in other types of digital electronic circuitry, or in computer software, firmware, or hardware, including the structures disclosed in this specification and their structural equivalents, or in combinations of one or more of them.

Aspects of the subject matter and the actions and operations described in this specification, for example, computing devices such as controller 165 and processes performed by controller 165 such as controlling switching of etching gasses of a plasma processing chamber, can be implemented in digital electronic circuitry, in tangibly-embodied computer software or firmware, in computer hardware, including the structures disclosed in this specification and their structural equivalents, or in combinations of one or more of them. The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively, or in addition, the carrier can be an artificially-generated propagated signal, e.g., a machine-generated electrical, optical, or electromagnetic signal, which is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages; and it can be deployed in any form, including as a stand-alone program, e.g., as an app, or as a module, component, engine, subroutine, or other unit suitable for executing in a computing environment, which environment can include one or more computers interconnected by a data communication network in one or more locations.

A computer program can, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or both, and any other kind of central processing unit. Generally, a central processing unit will receive instructions and data from a read-only memory or a random-access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. The mass storage devices can be, for example, magnetic, magneto-optical, or optical disks, or solid-state drives. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well; for example, feedback and responses provided to the user can be any form of sensory feedback, e.g., visual, auditory, speech or tactile; and input from the user can be received in any form, including acoustic, speech, or tactile input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., a smartphone or electronic tablet. Also, a computer can interact with a user by sending text messages or other forms of message to a personal device, e.g., a smartphone that is running a messaging application, and receiving responsive messages from the user in return.

This specification uses the term “configured to” in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

While this specification contains many specific implementation details, these should not be construed as limitations on the scope of what is being claimed, which is defined by the claims themselves, but rather as descriptions of features that can be specific to particular implementations of particular inventions. Certain features that are described in this specification in the context of separate implementations can also be implemented in combination in a single embodiment. Conversely, various features that are described in the context of a single embodiment can also be implemented in multiple implementations separately or in any suitable subcombination. Moreover, although features can be described above as acting in certain combinations and even initially be claimed as such, one or more features from a claimed combination can in some cases be excised from the combination, and the claim can be directed to a subcombination or variation of a subcombination.

Similarly, while operations are depicted in the drawings and recited in the claims in a particular order, this by itself should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

What is claimed is:

1. A substrate support component of a substrate support embodied in a machine-readable medium for designing, manufacturing, or testing a design, the substrate support component comprising:
an integrally formed insulator body comprising a first surface and a second surface opposite the first surface, wherein
the first surface is configured to retain a first body of the substrate support formed from an electrically conductive material,
the second surface is configured to affix the insulator body to a second body of the substrate support, wherein the second body is formed from an electrically conductive material, and
a thickness of the insulator body exceeds an arcing threshold between the first body and the second body when the insulator body is arranged between the first body and the second body; and
one or more gas conduits within the insulator body, the one or more gas conduits extending from the first surface to the second surface and forming a gas flow path from the first surface to the second surface, each of the one or more gas conduits comprising:
a gas conductance plug embedded within a first portion of the gas conduit and having at least a threshold gas conductance through the gas conductance plug,
wherein the gas conductance plug obstructs an electrical discharge path between the first body and the second body when the insulator body is arranged with respect to the first body and the second body.

2. The substrate support component embodied in the machine-readable medium of claim 1, wherein the insulator body further comprises a lattice region defining a volume embedded within the insulator body and comprising at least a threshold impedance.

3. The substrate support component embodied in the machine-readable medium of claim 1, wherein the one or more gas conduits further comprises a second portion having a second conductance, wherein the second portion is arranged between the first portion and the second surface.

4. The substrate support component embodied in the machine-readable medium of claim 3, wherein the second portion comprises a diameter smaller than a diameter of the first portion.

5. The substrate support component embodied in the machine-readable medium of claim 1, wherein two or more gas conduits comprise respective gas conductance plugs having different threshold gas conductance.

6. The substrate support component embodied in the machine-readable medium of claim 1, wherein the insulator body comprises a first material and the gas conductance plug comprises a second material.

7. The substrate support component embodied in the machine-readable medium of claim 1, wherein the gas conductance plug obstructs the electrical discharge path for a threshold voltage difference between the first surface and the second surface of the insulator body.

8. The substrate support component embodied in the machine-readable medium of claim 1, wherein gas conductance plug forms a convoluted gas flow path from a first surface of the gas conductance plug to a second surface of the gas conductance plug having the threshold gas conductance.

9. The substrate support component embodied in the machine-readable medium of claim 8, wherein the gas conductance plug comprises a gas conductance based on an internal structure of the gas conductance plug.

10. The substrate support component embodied in the machine-readable medium of claim 9, wherein the gas conductance of the gas conductance plug depends in part on a variable porosity of the gas conductance plug.

11. The substrate support component embodied in the machine-readable medium of claim 1, wherein the one or more gas conduits further comprise a sleeve surrounding an outer circumference of the gas conductance plug, wherein there is no radial gap between the gas conductance plug and the sleeve.

12. The substrate support component embodied in the machine-readable medium of claim 1, wherein the gas conductance plug comprises variable porosity along an axis of the gas flow path.

13. The substrate support component embodied in the machine-readable medium of claim 1, wherein the substrate support component resides on storage medium as a data format used for an exchange of layout data.

14. A substrate support component of a substrate support comprising:
an integrally formed insulator body comprising a first surface and a second surface opposite the first surface, wherein
the first surface is configured to retain a first body of the substrate support comprises an electrically conductive material,
the second surface is configured to affix the insulator body to a second body of the substrate support, wherein the second body comprises an electrically conductive material, and
a thickness of the insulator body exceeds an arcing threshold between the first body and the second body when the insulator body is arranged between the first body and the second body; and
one or more gas conduits within the insulator body, the one or more gas conduits extending from the first surface to the second surface and forming a gas flow path from the first surface to the second surface, each of the one or more gas conduits comprising:
a gas conductance plug embedded within a first portion of the gas conduit and having at least a threshold gas conductance through the gas conductance plug,
wherein the gas conductance plug obstructs an electrical discharge path between the first body and the second body when the insulator body is arranged with respect to the first body and the second body.

15. The substrate support component of claim 14, wherein the insulator body further comprises a lattice region defining a volume embedded within the insulator body and comprising at least a threshold impedance.

16. The substrate support component of claim 14, wherein the gas conductance plug obstructs the electrical discharge path for a threshold voltage difference between the first surface and the second surface of the insulator body.

17. The substrate support component of claim 16, wherein gas conductance plug forms a convoluted gas flow path from a first surface of the gas conductance plug to a second surface of the gas conductance plug having the threshold gas conductance.

18. A method of manufacturing a substrate support, the method comprising:
forming, by an additive manufacturing system, a plurality of layers, the plurality of layers comprising:
an insulator body comprising a first surface and a second surface opposite the first surface, wherein
the first surface is configured to retain a first body of the substrate support comprising an electrically conductive material,
the second surface is configured to affix the insulator body to a second body of the substrate support, wherein the second body comprises an electrically conductive material, and
a thickness of the insulator body exceeds an arcing threshold between the first body and the second body when the insulator body is arranged between the first body and the second body; and
wherein, during the forming of the plurality of layers, the methods further comprise:
forming one or more gas conduits within the insulator body, the one or more gas conduits extending from the first surface to the second surface and forming a gas flow path from the first surface to the second surface.

19. The methods of claim 18, wherein forming each of the one or more gas conduits comprises forming a gas conductance plug embedded within a first portion of the gas conduit and having at least a threshold gas conductance through the gas conductance plug,
wherein the gas conductance plug obstructs an electrical discharge path between the first body and the second body when the insulator body is arranged with respect to the first body and the second body.

20. The methods of claim 18, wherein forming the insulator body further comprises forming a lattice region defining a volume embedded within the insulator body and comprising at least a threshold impedance.

21. A substrate support component of a substrate support embodied in a machine-readable medium for designing, manufacturing, or testing a design, the substrate support component comprising:
a conductor body comprising an edge portion and a center portion, wherein the conductor body is configured to support an electrostatic chuck on a first surface of the conductor body;
one or more cooling channels embedded within the conductor body and configured to facilitate coolant flow within at least one of the edge portion and the center portion of the conductor body, wherein the one or more cooling channels comprise a plurality of cooling fins,
wherein the plurality of cooling fins include a first cross-section geometry oriented perpendicular to the coolant flow, and
wherein the plurality of cooling fins include a second geometry having a threshold surface area parallel to the coolant flow;
a first gas conduit embedded in the conductor body configured to facilitate gas flow through the conductor body and couple into one or more second gas conduits of the electrostatic chuck, when the electrostatic chuck is supported by the first surface; and
one or more isolation features integrally formed within the conductor body and oriented to reduce a threshold cross-talk between the edge portion of the conductor body and the center portion of the conductor body.

22. The substrate support component embodied in the machine-readable medium of claim 21, wherein the one or more isolation features comprise thermal isolation features.

23. The substrate support component embodied in the machine-readable medium of claim 22, wherein the one or more isolation features are arranged with respect to the conductor body to yield a lateral temperature distribution across the conductor body.

24. The substrate support component embodied in the machine-readable medium of claim 21, further comprising a coating formed on an outer portion of the conductor body and configured to generate a threshold electrical isolation.

25. The substrate support component embodied in the machine-readable medium of claim 24, wherein the coating comprises a ceramic material.

26. The substrate support component embodied in the machine-readable medium of claim 21, wherein a first surface of the conductor body is configured to retain an electrostatic chuck and a second, opposing surface of the conductor body is configured to affix to an insulator body of the substrate support.

27. The substrate support component embodied in the machine-readable medium of claim 21, wherein the substrate support component resides on storage medium as a data format used for an exchange of layout data.

28. A substrate support component of a substrate support comprising:
a conductor body comprising an edge portion and a center portion, wherein the conductor body is configured to support an electrostatic chuck on a first surface of the conductor body;
one or more cooling channels embedded within the conductor body and configured to facilitate coolant flow within at least one of the edge portion and the center portion of the conductor body, wherein the one or more cooling channels comprise a plurality of cooling fins,
wherein the plurality of cooling fins include a first cross-section geometry oriented perpendicular to the coolant flow, and
wherein the plurality of cooling fins include a second geometry having a threshold surface area parallel to the coolant flow;
a first gas conduit embedded in the conductor body configured to facilitate gas flow through the conductor body and couple into one or more second gas conduits of the electrostatic chuck, when the electrostatic chuck is supported by the first surface; and
one or more isolation features integrally formed within the conductor body and oriented to reduce a threshold cross-talk between the edge portion of the conductor body and the center portion of the conductor body.

29. The substrate support component of claim 28, wherein the one or more isolation features comprise thermal isolation features.

30. The substrate support component of claim 29, wherein the one or more isolation features are arranged with respect to the conductor body to yield a lateral temperature distribution across the conductor body.

31. The substrate support component of claim 28, further comprising a coating formed on an outer portion of the conductor body and configured to generate a threshold electrical isolation.

32. The substrate support component of claim 31, wherein the coating comprises a ceramic material.

33. The substrate support component of claim 28, wherein a first surface of the conductor body is configured to retain an electrostatic chuck and a second, opposing surface of the conductor body is configured to affix to an insulator body of the substrate support.

34. A method of manufacturing a substrate support, the method comprising:
forming, by an additive manufacturing system, a plurality of layers, the plurality of layers comprising:
a conductor body comprising an edge portion and a center portion, wherein the conductor body is configured to support an electrostatic chuck on a first surface of the conductor body,
wherein, during the forming of the plurality of layers, the methods further comprise:
forming one or more cooling channels within the conductor body and configured to facilitate coolant flow within at least one of the edge portion and the center portion of the conductor body, wherein the one or more cooling channels comprise a plurality of cooling fins,
forming a first gas conduit within the conductor body configured to facilitate gas flow through the conductor body and couple into one or more second gas conduits of the electrostatic chuck, when the electrostatic chuck is supported by the first surface; and
forming one or more isolation features integrally within the conductor body and oriented to reduce a threshold cross-talk between the edge portion of the conductor body and the center portion of the conductor body.

35. The method of claim 34, wherein the plurality of cooling fins include a first cross-section geometry oriented perpendicular to the coolant flow, and
wherein the plurality of cooling fins include a second geometry having a threshold surface area parallel to the coolant flow.

36. The method of claim 34, wherein forming the one or more isolation features comprises forming thermal isolation features.

37. The method of claim 36, wherein forming the one or more isolation features comprises forming the one or more isolation features with respect to the conductor body to yield a lateral temperature distribution across the conductor body.

38. The method of claim 34, further comprising forming a coating on an outer portion of the conductor body and configured to generate a threshold electrical isolation.

39. The method of claim 38, wherein the coating comprises a ceramic material.

40. The method of claim 34, wherein a first surface of the conductor body is configured to retain an electrostatic chuck and a second, opposing surface of the conductor body is configured to affix to an insulator body of the substrate support.
